(19) United States
(12) Patent Application Publication
(10) Pub. No.: US 2025/0253191 A1
(43) Pub. Date: Aug. 7, 2025

(54) METHODS OF MANUFACTURING INTERCONNECT STRUCTURES

(71) Applicant: Applied Materials, Inc., Santa Clara, CA (US)

(72) Inventors: Chandan Das, Singapore (SG); Bencherki Mebarki, Santa Clara, CA (US); Mohammad Mahdi Tavakoli, Sunnyvale, CA (US); Jiecong Tang, Singapore (SG); Bhaskar Jyoti Bhuyan, San Jose, CA (US); John Sudijono, Singapore (SG); Joung Joo Lee, San Jose, CA (US); Mark Saly, Santa Clara, CA (US)

(73) Assignee: Applied Materials, Inc., Santa Clara, CA (US)

(21) Appl. No.: 18/433,681

(22) Filed: Feb. 6, 2024

(51) Int. Cl. H01L 21/768

(52) U.S. Cl. CPC H01L 21/76843; H01L 21/76877

(57) ABSTRACT

Methods of manufacturing interconnect structures as part of a microelectronic device fabrication process are described. The methods include forming a dielectric layer including at least one feature defining a gap having sidewalls and a bottom on a substrate. The methods further include selectively depositing a metal-containing layer directly on the bottom; forming a blocking layer directly on the metal-containing layer; selectively forming a transition metal dichalcogenide (TMDC) film on the sidewalls; removing the blocking layer; and performing a gap fill process to fill the gap with a gapfill material.

### TECHNICAL FIELD

Embodiments of the disclosure generally relate to methods of manufacturing interconnect structures as part of a microelectronic device fabrication process. More particularly, embodiments of the disclosure are directed to methods of transition metal dichalcogenide (TMDC) films for barrier and liner material applications in microelectronic device fabrication processes.

### BACKGROUND

The semiconductor processing industry continues to strive for larger production yields while increasing the uniformity of layers deposited on substrates having larger surface areas. These same factors in combination with new materials also provide higher integration of circuits per unit area of the substrate. As circuit integration increases, the need for greater uniformity and process control regarding layer thickness rises. As a result, various technologies have been developed to deposit layers on substrates in a cost-effective manner, while maintaining control over the characteristics of the layer.

Chemical vapor deposition (CVD) is one of the most common deposition processes employed for depositing layers on a substrate. CVD is a flux-dependent deposition technique that requires precise control of the substrate temperature and the precursors introduced into the processing chamber in order to produce a desired layer of uniform thickness. These requirements become more critical as substrate size increases, creating a need for more complexity in chamber design and gas flow technique to maintain adequate uniformity.

A variant of CVD that demonstrates excellent step coverage is cyclical deposition or atomic layer deposition (ALD). Cyclical deposition is based upon atomic layer epitaxy (ALE) and employs chemisorption techniques to deposit precursor molecules on a substrate surface in sequential cycles. The cycles include exposing the substrate surface to a first precursor, a purge gas, a second precursor, and the purge gas. The first and second precursors react to form a product compound as a film on the substrate surface. The cycles may be repeated to form the layer to a desired thickness.

Multiple challenges impede power and performance improvements when scaling transistors and interconnects to the 3 nm node, 2 nm node, 1.4 nm node, and beyond. Interconnects include metal lines that transfer current within the same device layer and metal vias that transfer current between layers. Pitch reduction narrows the width of both and increases resistance, and also increases the voltage drop across a circuit, throttling circuit speed and increasing power dissipation.

While transistor performance improves with scaling, the same cannot be said for interconnect metals in back-end-of-line (BEOL) processes. As dimensions shrink, interconnect via resistance can increase by a factor of 10. An increase in interconnect via resistance may result in resistive-capacitive (RC) delays that reduce performance and increases power consumption.

A conventional copper interconnect structure includes a barrier layer and/or a metal liner deposited on the sidewalls of a gap that provide a via, the sidewalls made of a dielectric material, providing good adhesion and preventing the copper from diffusing into the dielectric layer. Barrier layers can typically be the largest contributor to via resistance due to high resistivity. Past approaches have focused on reducing the thickness of barrier layers or finding barrier layers with lower resistivity to decrease via resistance. Increased via resistance remains an issue, especially in smaller features when barrier layers on sidewalls form an increasing percentage of the via volume.

The advancing complexity of advanced microelectronic devices is placing stringent demands on currently used deposition techniques. Unfortunately, there is a limited number of viable chemical precursors and processes to provide films with suitable crystallinity, grain size, continuity, and electrical conductivity.

For example, conventional copper interconnect structures are reactive to chalcogens, e.g., oxygen (O₂), sulfur(S), selenium (Se), tellurium (Te), even at room temperature. Chalcogen exposure to copper increases BEOL via resistance and can pose microelectronic device reliability issues. As such, growth of transition metal dichalcogenide (TMDC) films on microelectronic devices with exposed copper remains a challenge.

Accordingly, there is a need for methods of depositing material layers that improve performance of interconnects, for example, by reducing via resistance and improving deposition selectivity.

### SUMMARY

One or more embodiments of the disclosure are directed to a method of manufacturing a microelectronic device. The method comprises forming a dielectric layer on a substrate. The dielectric layer includes at least one feature defining a gap having sidewalls and a bottom. The method further comprises selectively depositing a metal-containing layer directly on the bottom; forming a blocking layer directly on the metal-containing layer; and selectively forming a transition metal dichalcogenide film on the sidewalls.

Additional embodiments of the disclosure are directed to a method of manufacturing a microelectronic device. The method comprises forming a dielectric layer on a substrate. The dielectric layer includes at least one feature defining a gap having sidewalls and a bottom. The method further comprises selectively depositing a metal-containing layer directly on the bottom; forming a blocking layer directly on the metal-containing layer; and selectively forming a transition metal dichalcogenide film on the sidewalls. In one or more embodiments, selectively forming the transition metal dichalcogenide film comprises: depositing a transition metal oxide film on the sidewalls by sequentially exposing the substrate to a transition metal precursor and an oxidant; and converting the transition metal oxide film to the transition metal dichalcogenide film by exposing the transition metal oxide film to a chalcogenide precursor. The method further comprises removing the blocking layer; and performing a gap fill process to fill the gap with a gapfill material comprising one or more of copper (Cu), tungsten (W), molybdenum (Mo), or cobalt (Co).

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments.

FIG. 1A illustrates a process flow diagram of a method of manufacturing a microelectronic device in accordance with one or more embodiments of the disclosure;

FIG. 1B illustrates a process flow diagram of a method of selectively forming a transition metal dichalcogenide (TMDC) film in accordance with one or more embodiments of the disclosure;

FIG. 1C illustrates a cross-sectional schematic view of a microelectronic device including a gap having sidewalls and a bottom in accordance with one or more embodiments of the disclosure;

FIG. 1D illustrates a metal-containing layer selectively deposited directly on the bottom of the gap in accordance with one or more embodiments of the disclosure;

FIG. 1E illustrates a blocking layer formed directly on the metal-containing layer of FIG. 1D in accordance with one or more embodiments of the disclosure;

FIG. 1F illustrates the TMDC film formed by the method of FIG. 1B selectively formed on the sidewalls of the gap in accordance with one or more embodiments of the disclosure;

FIG. 1G illustrates removal of the blocking layer of FIG. 1E in accordance with one or more embodiments of the disclosure; and

FIG. 1H illustrates filling the gap with a gapfill material in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of +15% or less, of the numerical value. For example, a value differing by +14%, +10%, +5%, +2%, +1%, +0.5%, or +0.1% would satisfy the definition of about.

Spatially relative terms, such as “beneath,” “below,” “lower,” “above,” “upper” and the like, may be used herein for ease of description to describe one element's relationship to another element(s) or feature(s) as illustrated in the FIGURES. It will be understood that the spatially relative terms are intended to encompass different orientations of the microelectronic device in use or operation in addition to the orientation depicted in the FIGURES. For example, if the microelectronic device in the FIGURES is turned over, elements described as “below” or “beneath” other elements would then be oriented “above” the other elements. Thus, the exemplary term “below” may encompass both an orientation of above and below. The microelectronic device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “certain embodiments,” “one or more embodiments,” “some embodiments,” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in some embodiments,” “in one embodiment,” or “in an embodiment” in various places throughout this specification are not necessarily referring to the same embodiment of the disclosure. In one or more embodiments, the particular features, structures, materials, or characteristics are combined in any suitable manner.

As used in this specification and the appended claims, the term “substrate” and “wafer” are used interchangeably, both referring to a surface, or portion of a surface, upon which a process acts. It will also be understood by those skilled in the art that reference to a substrate can also refer to only a portion of the substrate, unless the context clearly indicates otherwise. Additionally, reference to “depositing on” or “forming on” a substrate can mean both a bare substrate and a substrate with one or more films or features deposited or formed thereon.

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Substrates include, without limitation, semiconductor wafers. In some embodiments, the semiconductor substrate comprises one or more of doped or undoped crystalline silicon (Si), doped or undoped crystalline silicon germanium (SiGe), doped or undoped amorphous silicon (Si), or doped or undoped amorphous silicon germanium (SiGe). Substrates may be exposed to a pretreatment process to polish, etch, reduce, oxidize, hydroxylate (or otherwise generate or graft target chemical moieties to impart chemical functionality), anneal and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used herein, the terms “precursor,” “reactant,” “reactive gas,” “reactive species,” and the like are used interchangeably to refer to any gaseous species that can react with the substrate surface.

Sputtering is a physical vapor deposition (PVD) process in which high-energy ions impact and erode a solid target and deposit the target material on the surface of a substrate, such as a semiconductor substrate. In semiconductor fabrication, the sputtering process is usually accomplished within a semiconductor fabrication chamber also known as a PVD processing chamber or a sputtering chamber. Sputtering has long been used for the deposition of metals and related materials in the fabrication of semiconductor integrated circuits.

Typically, the sputtering chamber comprises an enclosure wall that encloses a process zone into which a process gas is introduced, a gas energizer to energize the process gas, and an exhaust port to exhaust and control the pressure of the process gas in the chamber. The chamber is used to sputter deposit a material from a sputtering target onto the semiconductor substrate. In the sputtering processes, the sputtering target is bombarded by energetic ions, such as a plasma, causing material to be knocked off the target and deposited as a film on the semiconductor substrate.

A typical semiconductor fabrication chamber has a target assembly including disc-shaped target of solid metal or other material supported by a backing plate that holds the target. To promote uniform deposition, the PVD chamber may have an annular concentric metallic ring, which is often called a shield, circumferentially surrounding the disc-shaped target.

Plasma sputtering may be accomplished using either DC sputtering or RF sputtering. Plasma sputtering typically includes a magnetron positioned at the back of a sputtering target including two magnets of opposing poles magnetically coupled at their back through a magnetic yoke to project a magnetic field into the processing space to increase the density of the plasma and enhance the sputtering rate from a front face of the target. Magnets used in the magnetron are typically closed loop for DC sputtering and open loop for RF sputtering.

As used herein, the term “chemical vapor deposition” refers to the exposure of at least one reactive species to deposit a layer of material on the substrate surface. In some embodiments, the chemical vapor deposition (CVD) process comprises mixing the two or more reactive species in the processing chamber to allow gas phase reactions of the reactive species and deposition. In some embodiments, the CVD process comprises exposing the substrate surface to two or more reactive species simultaneously. In some embodiments, the CVD process comprises exposing the substrate surface to a first reactive species continuously with an intermittent exposure to a second reactive species. In some embodiments, the substrate surface undergoes the CVD reaction to deposit a layer having a predetermined thickness. In the CVD process, the layer can be deposited in one exposure to the mixed reactive species or can be multiple exposures to the mixed reactive species with purges between. In some embodiments, the substrate surface is exposed to the first reactive species and the second reactive species substantially simultaneously.

As used herein, “substantially simultaneously” means that most of the duration of the first reactive species exposure overlaps with the second reactive species exposure.

As used herein, the term “purging” includes any suitable purge process that removes unreacted precursor, reaction products and by-products from the process region. The suitable purge process includes moving the substrate through a gas curtain to a portion or sector of the processing region that contains none or substantially none of the reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the reaction chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

“Cyclical deposition” or “atomic layer deposition” (ALD) refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially. In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired layer or layer thickness is formed on the substrate surface. In either scenario, the ALD process of pulsing compound A, purge gas, compound B and purge gas is a cycle. A cycle can start with either compound A or compound B and continue the respective order of the cycle until achieving a layer with the predetermined thickness.

One or more of the layers deposited on the substrate or substrate surface are continuous. As used herein, the term “continuous” refers to a layer that covers an entire exposed surface without gaps or bare spots that reveal material underlying the deposited layer. A continuous layer may have gaps or bare spots with a surface area less than about 15% or less than about 10% of the total surface area of the layer.

Some embodiments of the disclosure provide methods for improving performance of interconnects. Interconnects comprise metal lines that transfer current within the same device layer, and metal vias that transfer current between layers. These lines and vias are formed with a conductive metal, such as, for example, copper (Cu) or cobalt (Co), in gaps formed within the microelectronic device. In one or more embodiments, a dielectric layer comprises at least one feature defining a gap having sidewalls and a bottom. In one or more embodiments, the gap includes the metal lines and the metal vias. In one or more embodiments, the metal lines have a sidewall and a bottom. In one or more embodiments, the metal vias have a sidewall and a bottom. As used in this specification and the appended claims, unless specified otherwise, reference to the “bottom of the gap” is intended to mean the bottom of the metal via, which is nearest the substrate surface.

Embodiments of the disclosure provide methods of manufacturing interconnect structures in a microelectronic device fabrication process. In one or more embodiments, the microelectronic devices described herein comprise at least one top interconnect structure that is interconnected to at least one bottom interconnect structure. Embodiments of the disclosure provide microelectronic devices and methods of manufacturing microelectronic devices that improve performance of interconnects, for example, reducing via resistance.

Transition metal dichalcogenides (TMDCs) are known to be great candidates to mitigate the issue of metal migration associated with downscaling of interconnect structures. Moreover, TMDCs possess better conductivity and carrier mobility compared to current processes in 3D-NAND devices. Typical TMDC deposition methods require high temperature processes which may not be compatible with device thermal budgets.

Conventional copper interconnect structures are reactive to chalcogens, e.g., oxygen (O₂), sulfur(S), selenium (Se), tellurium (Te), even at room temperature. Chalcogen exposure to copper increases BEOL via resistance and can pose microelectronic device reliability issues. As such, growth of transition metal dichalcogenide (TMDC) films on microelectronic devices with exposed copper remains a challenge.

Embodiments of the disclosure advantageously provide methods of forming TMDC films in interconnect structures (e.g., copper interconnect structures) such that via resistance is not affected. Some advantageously provide methods of forming TMDC films in copper interconnect structures such that copper does not react with the TMDC film. Some embodiments advantageously provide methods that include selectively forming a metal-containing layer (including a metallic material other than copper) on the bottom of the gap and forming a blocking layer directly on the metal-containing layer for selective growth of a TMDC film on the sidewalls of the gap.

Some embodiments advantageously provide a pathway to grow TMDC films at lower temperatures, such as in a range of from about 150° C. to about 500° C., or in a range of from about 150° C. to about 450° C., which is suitable for device integration in temperature sensitive structures and devices. Embodiments of the disclosure provide methods of forming high-quality TMDC films in terms of crystallinity, grain size, continuity, and electrical conductivity for use as a channel material, a barrier material, or a liner material in the miniaturization and scaling of integrated circuits. Embodiments of the disclosure provide methods of forming high-quality 2D-TMDC films for temperature-sensitive device architectures.

Embodiments of the disclosure advantageously provide conformally deposited crystalline TMDC films which can be used in memory and logic applications, such as, for example, barrier and liner material applications in BEOL processes. For example, the TMDC film acting as a barrier/liner may enable nucleation of a subsequently deposited metal, adhesively bind a metal to underlying dielectric materials, and block diffusion of metal elements to underlying dielectric materials. The TMDC films can advantageously be used in high aspect ratio structures. The TMDC films can advantageously be used in interconnect structures, such as, for example, copper interconnect structures.

Embodiments of the disclosure advantageously provide methods of forming TMDC films via a low energy barrier pathway. In some embodiments, in the low energy barrier pathway, the transition metal precursors are used in their various forms (metal, metal oxide, metal chloride, metal oxychloride, and the like). In one or more embodiments, the methods include depositing an ultrathin layer to a few nm thick, followed by oxidation, then exposure to a chalcogenide precursor, (e.g., sulfurization), which forms high-quality TMDC films. Advantageously, the methods described herein provide a low energy barrier pathway for sulfurization of transition metals or their precursors to metal sulfides. Based on this low energy barrier pathway, the methods advantageously form a conformal and continuous TMDC film, such as a tungsten disulfide (WS₂) film. Some embodiments provide methods of forming TMDC films by thermal (e.g., without the use of plasma) or plasma-based processes.

The embodiments of the disclosure are described by way of the FIGURES, which illustrate processes and substrates in accordance with one or more embodiments of the disclosure. The processes, schemes, and resulting substrates shown are merely illustrative of the disclosed processes, and the skilled artisan will recognize that the disclosed processes are not limited to the illustrated applications.

In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

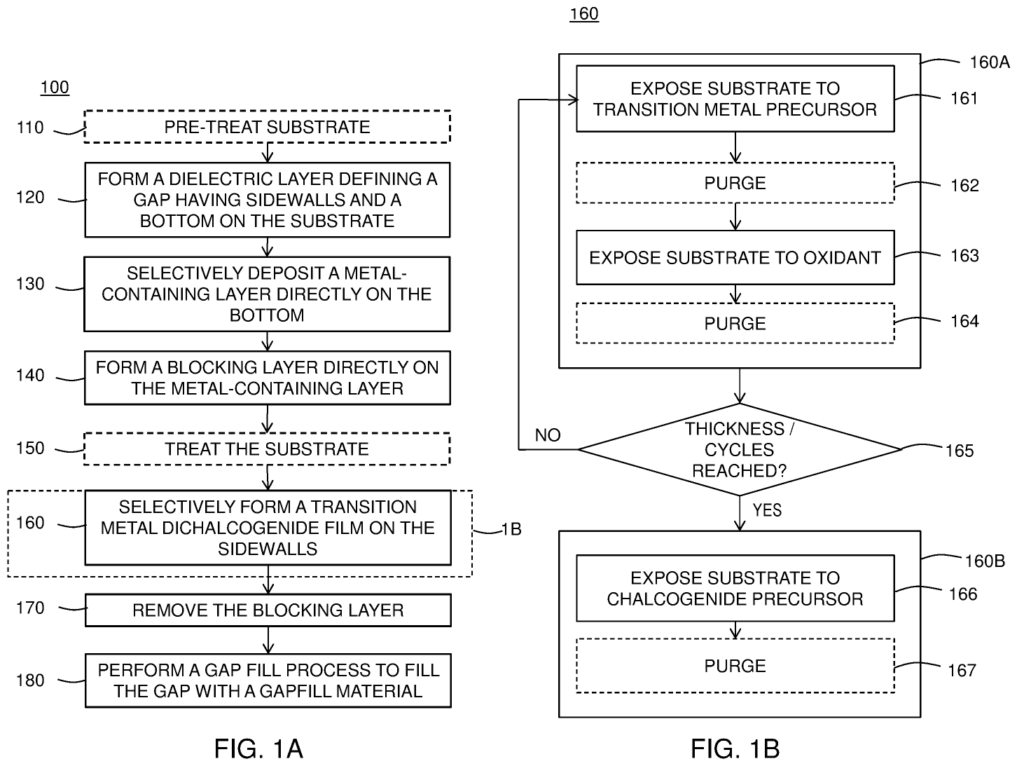

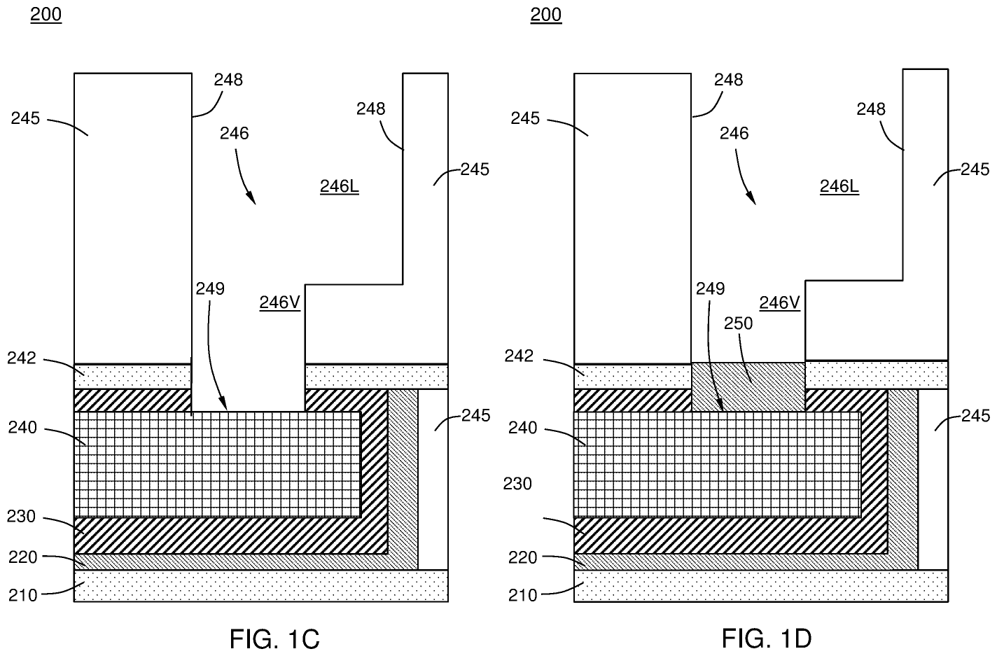

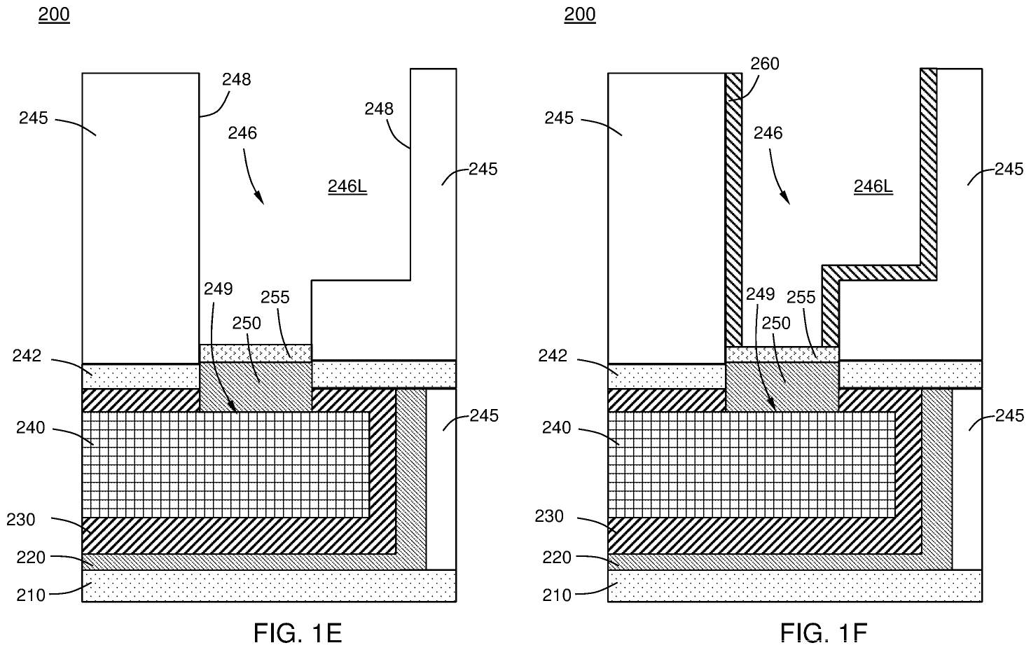

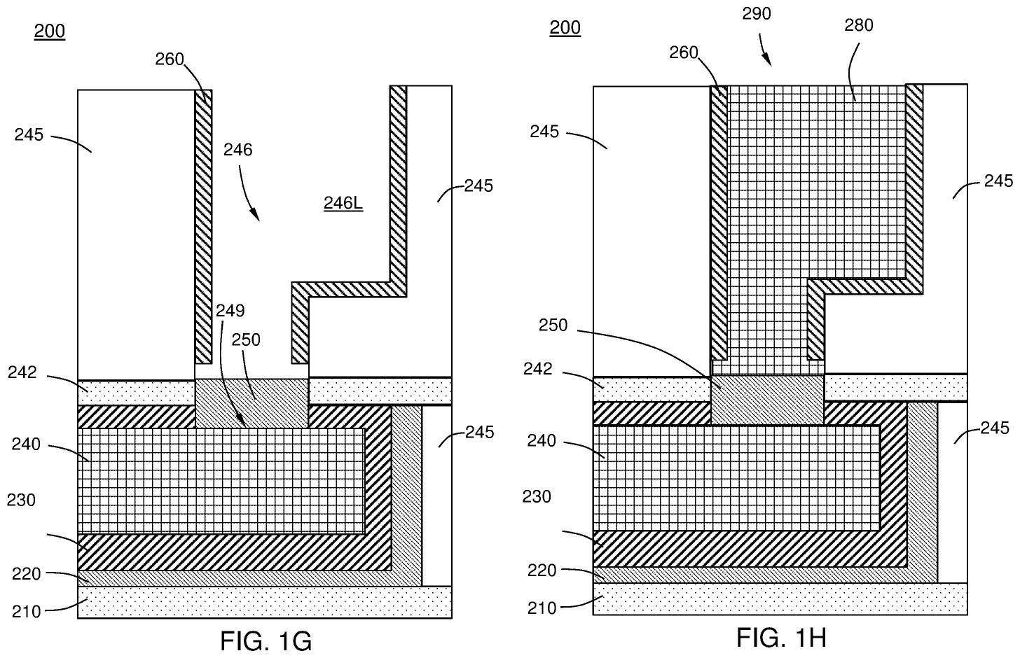

Methods of manufacturing microelectronic devices are described herein with reference to FIGS. 1A-1H. FIG. 1A is a process flow diagram of an exemplary method 100 of manufacturing a microelectronic device 200. FIG. 1B is a process flow diagram of operation 160 of the method 100, e.g., an exemplary method of forming a transition metal dichalcogenide (TMDC) film 260. FIGS. 1C-1H illustrate stages of manufacture of the microelectronic device 200 during the method 100.

The methods according to one or more embodiments, e.g., method 100, generally refer to methods of manufacturing microelectronic devices and more particularly refer to methods of manufacturing interconnect structures as part of a microelectronic device fabrication process. Accordingly, it will be appreciated by the skilled artisan that one or more additional operations needed to complete the fabrication of a microelectronic device are known to the skilled artisan and are within the scope of the present disclosure without undue experimentation.

Referring to FIG. 1A, the method 100 optionally includes, at operation 110, pre-cleaning a substrate 210. In one or more embodiments, keeping the pre-cleaning process under vacuum ensures that no oxide is introduced/formed on the substrate 210 during the method 100. At operation 110, pre-cleaning the substrate 210 removes native oxides from the surface of the substrate 210.

The pre-cleaning process of operation 110 can be any suitable process. In some embodiments, the pre-cleaning process of operation 110 removes polymeric residues and copper oxide from the interconnect structure and maintains the integrity of the dielectric surface. As used herein, the term “substrate 210” can be used to refer to a substrate and/or a pre-cleaned substrate, unless the context clearly indicates otherwise.

At operation 120, the method 100 comprises forming a dielectric layer 245 on the substrate 210, e.g., the pre-cleaned substrate. The dielectric layer 245 comprises at least one feature defining a gap 246 having sidewalls 248 and a bottom 249. At operation 130, the method 100 comprises selectively depositing a metal-containing layer 250 directly on the bottom 249. At operation 140, the method 100 comprises forming a blocking layer 255 directly on the metal-containing layer 250. At operation 150, the method 100 optionally includes treating the substrate 210. At operation 160, the method 100 comprises selectively forming a transition metal dichalcogenide (TMDC) film 260 on the sidewalls 248. At operation 170, the method 100 comprises removing the blocking layer 255. At operation 180, the method 100 comprises performing a gap fill process to fill the gap 246 with a gapfill material 280.

In one or more embodiments, the method 100 comprises operation 110, operation 120, operation 130, operation 140, operation 150, operation 160, operation 170, and operation 180. In one or more embodiments, the method 100 consists essentially of operation 110, operation 120, operation 130, operation 140, operation 150, operation 160, operation 170, and operation 180. In one or more embodiments, the method 100 consists of operation 110, operation 120, operation 130, operation 140, operation 150, operation 160, operation 170, and operation 180. In one or more embodiments, the method 100 consists of operation 130 (where the dielectric layer 245 on the substrate 210, e.g., a pre-cleaned substrate, is provided), operation 140, operation 150, operation 160, operation 170, and operation 180.

In one or more embodiments, operation 160 represents an exemplary method (illustrated in FIG. 1B) of forming the TMDC film 260, shown in FIG. 1F.

FIG. 1B is representative of an atomic layer deposition (ALD) process in which the semiconductor substrate, e.g., substrate 210, is exposed sequentially to the reactive gases in a manner that prevents or minimizes gas phase reactions of the reactive gases. In so doing, operation 160 advantageously avoids a chemical vapor deposition (CVD) process in which the reactive gases are mixed in the processing chamber to allow gas phase reactions of the reactive gases.

The TMDC film 260 is selectively formed on sidewalls 248 in two phases: a first phase 160A and a second phase 160B. The first phase 160A comprises operation 161, operation 162, operation 163, operation 164, and decision 165, to form a transition metal oxide film on the sidewalls 248. In the first phase 160A, the transition metal oxide film is directly formed without forming a transition metal film intermediate. The second phase 160B comprises operation 166 and operation 167 to convert the transition metal oxide film formed in the first phase 160A to a transition metal dichalcogenide film, e.g., the TMDC film 260.

The first phase 160A may be repeated to form the transition metal oxide film to a desired thickness (decision 165). If the transition metal oxide film is formed to the desired thickness in the first phase 160A, (e.g., the thickness/cycle is reached, denoted by “YES” in FIG. 1B) operation 160 moves to the second phase 160B. If the transition metal oxide film is not formed to the desired thickness in the first phase 160A, (e.g., the thickness/cycle is not reached, denoted by “NO” in FIG. 1B) operation 160 moves to the beginning of operation 160, e.g., operation 161, to form the transition metal oxide film to the desired thickness.

In some embodiments, the second phase 160B is performed after the first phase 160A has deposited the transition metal oxide film to a predetermined thickness. In some embodiments, the second phase 160B is performed after a single cycle of the first phase 160A. In some embodiments, the second phase 160B is performed after multiple cycles of the first phase 160A.

The first phase 160A comprises sequentially exposing the substrate 210 to a transition metal precursor at operation 161, optionally purging the substrate 210 at operation 162, exposing the substrate to an oxidant at operation 163, and optionally purging the substrate 210 at operation 164 to deposit the transition metal oxide film. In some embodiments, the first phase 160A consists essentially of operation 161, operation 162, operation 163, operation 164, and decision 165. In some embodiments, the first phase 160A consists of operation 161, operation 162, operation 163, operation 164, and decision 165.

The second phase 160B comprises sequentially exposing the substrate 210 to a chalcogenide precursor at operation 166 and, optionally, purging the substrate surface at operation 167 to convert the transition metal oxide film to the transition metal dichalcogenide film, e.g., the TMDC film 260. In some embodiments, the second phase 160B consists essentially of operation 166 and operation 167. In some embodiments, the second phase 160B consists of operation 166 and operation 167.

It has been observed that the substrate 210, such as, for example, a low-K dielectric substrate surface, such as the sidewalls 248, is sensitive to strong oxidants while growing the transition metal oxide film in the first phase 160A. It remains a challenge for the transition metal precursors to adsorb on inherently highly hydrophobic alkyl-group terminated dielectric surfaces, such as the sidewalls 248.

In some embodiments, the method 100 comprises treating the substrate 210 at operation 150 with a plasma treatment or ultraviolet (UV) radiation exposure prior to forming the TMDC film 260. In some embodiments, the method 100 comprises treating the substrate 210 at operation 150 with the plasma treatment or ultraviolet (UV) radiation exposure to remove surface alkyl groups and make the low-K dielectric surface suitable for precursor adsorption. Advantageously, the oxidant comprising one or more of an alcohol or deionized/deoxygenated water does not damage the low-K dielectric surface, such as the sidewalls 248. Additionally, use of the transition metal precursors and the oxidant comprising one or more of an alcohol or deionized/deoxygenated water advantageously enables uniform growth of the transition metal oxide film without modifying the properties of, or damaging, the low-K dielectric surface, such as the sidewalls 248.

In one or more embodiments, the plasma treatment of operation 150 comprises exposing the substrate 210 to a plasma of carbon dioxide (CO₂). In one or more embodiments, the plasma of CO₂ further comprises an inert gas, including, but not limited to, argon (Ar), helium (He), or nitrogen (N₂). In one or more embodiments, the substrate 210 is exposed to the plasma of CO₂ for a time period in a range of from about 0.5 seconds to about 20 seconds.

Without intending to be bound by theory, it is thought that the K-value of the low-K dielectric substrate surface, such as silicon oxycarbide (SiOC), is dependent on the oxidant used during the method 100. It has been advantageously found that the oxidant described herein does not change the K-value and is suitable for deposition on a low-K dielectric substrate surface, such as the sidewalls 248.

In one or more embodiments, the stoichiometry of the TMDC film 260 was measured by x-ray photoelectron spectroscopy (XPS). In one or more embodiments, a TMDC film 260 comprising WS₂ and having a stoichiometric ratio of sulfur:tungsten in a range of from 1:1 to 1:2 with impurities, e.g., carbon (C), nitrogen (N₂), and/or oxygen (O₂), such as about 5% nitrogen (N₂), does not change the K-value and is suitable for deposition on a low-K dielectric substrate surface, such as the sidewalls 248.

In specific embodiments, it has advantageously been found that exposing the substrate 210 to the plasma of CO₂ for a time period in a range of from about 0.5 seconds to about 20 seconds does not modify the properties of, or damage, the low-K dielectric surface, such as the sidewalls 248, where there is no change in K-value.

In one or more embodiments, the pre-treatment of operation 155 comprises exposing the substrate 210 to ultraviolet (UV) radiation. In one or more embodiments, the pre-treatment of operation 150 comprises exposing the substrate 210 to UV radiation for a time period in a range of from about 0.5 seconds to about 30 seconds. In one or more embodiments, exposing the substrate 210 to UV radiation includes using a UV lamp that generates the UV radiation.

In the first phase 160A, in one or more embodiments, at operation 161, the substrate 210 is exposed to a transition metal precursor to selectively form a reactive metal species on the sidewalls 248. The reactive metal species does not form on the bottom 249 due to the presence of the metal-containing layer 250 directly on the bottom 249 and the blocking layer 255 directly on the metal-containing layer 250.

The transition metal precursor can be any suitable transition metal containing compound that can react (i.e., adsorb or chemisorb) onto the substrate 210 (more specifically, the sidewalls 248) to leave a transition metal containing species on the sidewalls 248. It is thought that any transition metal containing compound, which, based on its size, can inhibit diffusion through pores in the sidewalls 248, where each pore has a size in a range of from 5 Å to 20 Å, is suitable.

In one or more embodiments, the transition metal precursor does not comprise oxygen or halogen atoms. In some embodiments, the transition metal precursor does not comprise, consist essentially of, or consist of oxygen or halogen atoms.

In one or more embodiments, the transition metal precursor comprises one or more of tungsten (W), molybdenum (Mo), tantalum (Ta), titanium (Ti), or ruthenium (Ru). In one or more embodiments, the transition metal precursor comprises, consists essentially of, or consists of one or more of bis(t-butylimino) bis(dimethylamino) tungsten (VI), bis(isopropylcyclopentadienyl) tungsten (IV) dihydride, bis(cyclopentadienyl) tungsten dihydride, bis(t-butylimino) bis(dimethylamino) molybdenum (VI), pentakis (dimethylamino) tantalum (V), or tetrakis (dimethylamido) titanium (IV).

At operation 162, the processing chamber and/or substrate 210 is optionally purged to remove unreacted transition metal precursor, reaction products, and byproducts. As used in this manner, the term “processing chamber” also includes portions of a processing chamber adjacent the substrate surface without encompassing the complete interior volume of the processing chamber. For example, in a sector of a spatially separated processing chamber, the portion of the processing chamber adjacent the substrate surface is purged of the transition metal precursor by any suitable technique including, but not limited to, moving the substrate through a gas curtain to a portion or sector of the processing chamber that contains none or substantially none of the transition metal precursor.

In one or more embodiments, purging the processing chamber comprises applying a vacuum. In some embodiments, purging the processing chamber comprises flowing a purge gas over the substrate 210. In some embodiments, the portion of the processing chamber refers to a micro-volume or small volume process station within a processing chamber. The term “adjacent” referring to the substrate surface means the physical space next to the surface of the substrate which can provide sufficient space for a surface reaction (e.g., precursor adsorption) to occur. In one or more embodiments, the purge gas is selected from one or more of nitrogen (N₂), helium (He), and argon (Ar).

The descriptors of the purge operations described herein, both in operation and composition, may apply to any of the purge operations of the method 100: operation 162, 164, and 167.

At operation 163, the substrate 210 is exposed to an oxidant to form a transition metal oxide film on the sidewalls 248. The oxidant (which may also be referred to as an oxide reactant) may be any suitable compound for oxidizing the adsorbed transition metal precursor to form a transition metal oxide film.

In some embodiments, the oxidant comprises one or more of water (H₂O), oxygen (O₂), ozone (O₃), an alcohol, or deionized/deoxygenated water. In some embodiments, the oxidant comprises one or more of water (H₂O), oxygen (O₂), or ozone (O₃). In some embodiments, the oxidant comprises one or more of an alcohol or deionized/deoxygenated water.

As described herein, it has been observed that the low-K dielectric substrate surface, such as the sidewalls 248, is sensitive to strong oxidants while growing the transition metal oxide film in the first phase 160A. It remains a challenge for the transition metal precursors to adsorb on inherently highly hydrophobic alkyl-group terminated dielectric surfaces, e.g., the sidewalls 248. In some embodiments, treating the substrate 210 at operation 150 comprises a plasma treatment or ultraviolet (UV) radiation exposure to remove surface alkyl groups and make the low-K dielectric surface (e.g., the sidewalls 248) suitable for precursor adsorption. Advantageously, the oxidant comprising one or more of an alcohol or deionized/deoxygenated water does not damage the low-K dielectric surface (e.g., the sidewalls 248). In some embodiments, the oxidant does not comprise a plasma, which, without intending to be bound by any particular theory, is also thought to damage the low-K dielectric surface (e.g., the sidewalls 248).

The alcohol can be any suitable alcohol. In one or more embodiments, the alcohol used for the oxidant comprises one or more of methanol, ethanol or isopropyl alcohol. In one or more embodiments, the alcohol used for the oxidant comprises isopropyl alcohol.

As used herein, “deionized/deoxygenated water” includes any water composition in which dissolved oxygen (DO) has been removed. In embodiments where the oxidant comprises deionized/deoxygenated water, DO can be removed by any suitable process known to the skilled artisan, and it is to be understood that the disclosure is not limited to any specific process.

At operation 164, the processing chamber and/or substrate 210 is optionally purged to remove unreacted oxidant, reaction products, and byproducts. The purge process of operation 164 may be the same purge process or a different purge process as operation 162.

In one or more embodiments, the transition metal oxide film is formed to a thickness in a range of 5 Å to 50 Å, in a range of 5 Å to 35 Å, in a range of 5 Å to 25 Å, or in a range of 5 Å to 10 Å. In accordance with decision 165, the first phase 160A, may be repeated until the transition metal oxide film is formed to the desired thickness.

It has been advantageously found that purging the processing chamber at operation 164 enhances the adsorption of the transition metal precursor if returning to the beginning of the first phase 160A to deposit additional transition metal oxide film. It has been found that the purge at operation 164 provides a “clean” substrate surface, which enhances the adsorption of the transition metal precursor. It has also been advantageously found that that the purge at operation 164 prevents or minimizes gas phase reactions of the reactive gases by purging out removes unreacted oxidant, reaction products, and byproducts. Without intending to be bound by theory, it is thought that not purging at operation 164 may otherwise lead to a chemical vapor deposition (CVD) process in which the reactive gases are mixed in the processing chamber to allow gas phase reactions of the reactive gases.

In some embodiments, the transition metal oxide film formed in the first phase 160A is directly formed without forming a transition metal film intermediate. The inventors have surprisingly found that the formation of certain metals (e.g., tungsten) on dielectric surfaces, e.g., the sidewalls 248 is more difficult (e.g., longer processing times, elevated temperatures) than the formation of metal oxides. Further, the formation of a metal layer which is subsequently oxidized requires more processing time and decreases processing throughput. Accordingly, embodiments of the disclosure advantageously provide methods of forming a transition metal oxide film without the formation of a metal film intermediate.

Once the first phase 160A is completed, and the transition metal oxide film has reached a predetermined thickness or a predetermined number of process cycles have been performed, operation 160 of the method 100 moves to the second phase 160B.

In the second phase 160B, the transition metal oxide film formed in the first phase 160A is converted to a transition metal dichalcogenide (TMDC) film, e.g., the TMDC film 260. In some embodiments, converting the transition metal oxide film comprises exposing the transition metal oxide film to a chalcogenide precursor at operation 166. The chalcogenide precursor comprises one of more of oxygen (O₂), sulfur(S), selenium (Se), tellurium (Te), polonium (Po), or livermorium (Lv). In some embodiments, the chalcogenide precursor comprises one of more of sulfur(S), selenium (Se), tellurium (Te). In some embodiments, the chalcogenide precursor comprises hydrogen sulfide (H₂S). In some embodiments, the chalcogenide precursor further comprises an inert gas, including, but not limited to, argon (Ar), helium (He), or nitrogen (N₂). In some embodiments, the chalcogenide precursor further comprises hydrogen (H₂). In some embodiments, the chalcogenide precursor does not comprise a plasma.

In one or more embodiments, the transition metal oxide film is exposed to a chalcogenide precursor comprising thermal Ar/H₂S or H₂/H₂S gas. In one or more embodiments, the transition metal oxide film is exposed to a chalcogenide precursor comprising a plasma formed from Ar/H₂S or H₂/H₂S gas. In one or more embodiments, the transition metal oxide film comprising tungsten (W) is converted to tungsten disulfide (WS₂) by exposing the substrate 210 to the chalcogenide precursor. In one or more embodiments, the transition metal oxide film comprising molybdenum (Mo) is converted to molybdenum disulfide (MoS₂) by exposing the substrate 210 to the chalcogenide precursor.

In one or more embodiments, where the chalcogenide precursor comprises a plasma, converting the transition metal oxide film to the TMDC film 260 is conducted at a plasma power in a range of from 25 watts (W) to 500 watts (W).

In one or more embodiments, converting the transition metal oxide film to the TMDC film 260 is conducted at a temperature in a range of from about 150° C. to about 500° C., in a range of from about 150° C. to about 450° C., or in a range of from about 300° C. to about 450° C.

In some embodiments, converting the transition metal oxide film to the TMDC film 260 is performed at a pressure in a range of from 0.1 Torr to 100 Torr. In some embodiments, converting the transition metal oxide film to the TMDC film 260 is performed at a pressure in a range of from, for example, 1 Torr to 100 Torr, in a range of from 1 Torr to 50 Torr, in a range of from 1 Torr to 30 Torr, or in a range of from 1 Torr to 10 Torr. In some embodiments, the transition metal oxide film is exposed to a chalcogenide precursor comprising thermal or plasma Ar/H₂S or H₂/H₂S gas in a range of from 1 Torr to 100 Torr.

In one or more embodiments, converting the transition metal oxide film to the TMDC film 260 is conducted for a time period in a range of from 1 minute to 60 minutes.

In one or more embodiments, the TMDC film 260 is substantially free of oxygen. As used herein, “substantially free” means that there is less than or equal to about 5%, including less than or equal to about 4%, less than or equal to about 3%, less than or equal to about 2%, less than or equal to about 1%, or less than or equal to about 0.5% of oxygen, on an atomic basis, in the TMDC film 260. It is thought that the TMDC film 260 that is formed without producing oxygen as a byproduct, advantageously minimizes the potential to etch/corrode underlying metal layers.

At operation 167, the processing chamber and/or substrate 210 is optionally purged to remove unreacted chalcogenide precursor, reaction products, and byproducts.

If the TMDC film 260 has reached a predetermined thickness or a predetermined number of cycles have been performed, the method 100 moves to an optional post-processing operation. If the thickness of the TMDC film 260 or the number of cycles has not reached the predetermined threshold, the method 100 returns to the beginning of the first phase 160A to form additional TMDC film.

In one or more embodiments, the method 100 further comprises repeating forming the transition metal oxide film in the first phase 160A and converting the transition metal oxide film to form the TMDC film 260 in the second phase 160B with a final thickness in a range of from 5 Angstroms (Å) to 300 Angstroms (Å). The final thickness of the TMDC film 260 can vary within the range of from 5 Angstroms (Å) to 300 Angstroms (Å) depending on the specific application for which the TMDC film 260 is used. In one or more specific embodiments, the TMDC film 260 has a final thickness in a range of from 5 Å to 10 Å. In one or more specific embodiments, the TMDC film 260 has a final thickness in a range of from 150 Å to 300 Å.

Advantageously, the TMDC film 260 acts as a barrier/liner that enables nucleation of a subsequently deposited metal, adhesively binds a metal to underlying dielectric materials, and block diffusion of metal elements, e.g., copper, to underlying dielectric materials, e.g., the dielectric layer 245.

Advantageously, the transition metal oxide film can be deposited on the sidewalls 248 (first phase 160A) and the transition metal oxide film can be converted to the TMDC film 260 (second phase 160B) in situ or ex situ.

Operation 160 of the method 100 can be performed at any suitable temperature depending on, for example, the transition metal precursor, oxidant, chalcogenide precursor, or thermal budget of the device. In one or more embodiments, the use of high temperature processing may be undesirable for temperature-sensitive substrates, such as logic devices. In one or more embodiments, the method 100 is performed at a temperature in a range of from 50° C. to 500° C. during the entirety of the method 100. In one or more embodiments, operation 160 of the method 100 is performed at a temperature in a range of about 150° C. to about 500° C., in a range of about 150° C. to about 450° C., or in a range of about 300° C. to about 450° C.

In some embodiments, exposure to the transition metal precursor (operation 161) occurs at a different temperature than the exposure to the oxidant (operation 163) or the chalcogenide precursor (operation 166). In some embodiments, exposure to the transition metal precursor and/or the oxidant occurs at a first temperature in a range of about 150° C. to about 300° C., and exposure to the chalcogenide precursor occurs at a second temperature in the range of about 300° C. to about 500° C. In some embodiments, both the transition metal precursor and the chalcogenide precursor are delivered at the same temperature.

FIGS. 1C-1H illustrate a portion of the microelectronic device 200 during stages of manufacture in accordance with method 100. In FIG. 1C, the microelectronic device 200 comprises the substrate 210, a barrier layer 220 on the substrate 210, a metal layer 230 on the barrier layer 220, a conductive filled gap 240, an aluminum oxide etch stop layer 242, and the dielectric layer 245 on the aluminum oxide etch stop layer 242. The dielectric layer 245 comprises at least one feature defining the gap 246 having sidewalls 248 and the bottom 249. It will be appreciated that in one or more embodiments, the conductive filled gap 40 forms a metal line that transfers current within the same device layer.

In one or more embodiments, the substrate 210 is a wafer, for example, a semiconductor substrate. In one or more embodiments, the substrate 210 is an etch stop layer on a wafer. In one or more embodiments, the substrate 210 is an aluminum oxide etch stop layer on a wafer.

In one or more embodiments, the barrier layer 220 comprises tantalum nitride (TaN). In one or more embodiments, the barrier layer 220 comprises tantalum nitride (TaN) formed by ALD.

In one or more embodiments, the metal layer 230 comprises one or more of ruthenium (Ru), copper (Cu), cobalt (cobalt), molybdenum (Mo), tantalum (Ta), or tungsten (W). In one or more embodiments, the metal layer 230 comprises one or more of copper (Cu), cobalt (cobalt), molybdenum (Mo), or tungsten (W). In one or more embodiments, a portion of the metal layer 230 is etched such that a portion of the conductive filled gap 240 is exposed. In one or more embodiments, a metal-containing layer 250 is deposited on the portion of the metal layer 230 that is etched. In specific embodiments, the metal-containing layer 250 is selectively deposited directly on the conductive filled gap 240.

In one or more embodiments, the conductive filled gap 240 comprises one or more of copper (Cu) or cobalt (Co). In one or more embodiments, the etch stop layer 242 comprises one or more of aluminum oxide, silicon nitride, or aluminum nitride.

In one or more embodiments, the dielectric layer 245 comprises a low-K dielectric material. In one or more embodiments, the dielectric layer 245 comprises silicon oxide (SiOₓ). In one or more embodiments, the dielectric layer 245 comprises SiOₓH_{y}(CH_{z}). Further embodiments provide that the dielectric layer 245 comprises porous or carbon-doped SiOₓ. In some embodiments, the dielectric layer 245 is a porous or carbon-doped SiOₓ layer with a K value less than about 5. In other embodiments, the dielectric layer 245 is a multilayer structure. For example, in one or more embodiments, the dielectric layer 245 comprises a multilayer structure having one or more of a dielectric layer, an etch stop layer, and a hard mask layer.

In one or more illustrated embodiments, the dielectric layer 245 comprises at least one feature defining the gap 246 having sidewalls 248 and the bottom 249. The FIGURES show substrates 210 having a single feature for illustrative purposes; however, those skilled in the art will understand that there can be more than one feature.

As used herein, the term “feature” means any intentional surface irregularity. Suitable examples of features include but are not limited to trenches which have a top, two sidewalls and a bottom, peaks which have a top and two sidewalls. Features can have any suitable aspect ratio (ratio of the depth of the feature to the width of the feature). In some embodiments, the aspect ratio is greater than or equal to about 5:1, 10:1, 15:1, 20:1, 25:1, 30:1, 35:1 or 40:1.

In some embodiments, the at least one feature defines a cylindrical via that, when filled with metal, transfers current between layers, and lines that transfer current within the same device layer. In some embodiments, the at least one feature defines the gap 246 in the dielectric layer 245. In some embodiments, the gap 246 defines a via portion 246V and a line portion 246L. In one or more embodiments, each of the via portion 246V and the line portion 246L independently have an aspect ratio that is greater than or equal to about 5:1, 10:1, 15:1, 20:1, 25:1, 30:1, 35:1 or 40:1.

The bottom 249 of the gap 246 is defined by the conductive filled gap 240. In one or more embodiments, the bottom 249 of the gap 246 comprises one or more of copper (Cu) or cobalt (cobalt). In one or more embodiments, the bottom 249 of the gap 246 comprises copper (Cu).

Some embodiments advantageously provide methods that include selectively forming a metal-containing layer (including a metallic material other than copper) on the bottom of the gap and forming blocking layer directly on the metal-containing layer for selective growth of TMDC film on the sidewalls of the gap.

In one or more embodiments, the metal-containing layer 250 is selectively deposited directly on the bottom 249 of the gap 246 in accordance with operation 130 of the method 100 (FIGS. 1A and 1D). Stated differently, in one or more embodiments, the metal-containing layer 250 is selectively deposited directly on the conductive filled gap 240 (e.g., one or more of copper (Cu) or cobalt (Co)), which defines the bottom 249 of the gap 246. In one or more embodiments, the metal-containing layer 250 is selectively deposited directly on the bottom 249 of the gap 246 such that there is direct contact between the elements (e.g., direct contact between the metal-containing layer 250 and the bottom 249 without intervening elements).

The metal-containing layer 250 may include any suitable metallic material. In one or more embodiments, the metal-containing layer 250 includes a metallic material other than the material of the conductive filled gap 240. In one or more embodiments, the metal-containing layer 250 includes a metallic material other than copper (Cu). In some embodiments, the metal-containing layer 250 serves as a protective layer that prevents diffusion of the material of the conductive filled gap 240 e.g., one or more of copper (Cu) or cobalt (Co), into the gap 246. In some embodiments, the metal-containing layer 250 comprises one or more of molybdenum (Mo), tungsten (W), ruthenium (Ru), iridium (Ir), osmium (Os), titanium (Ti), tantalum (Ta), molybdenum nitride (MoN), tungsten nitride (WN), ruthenium nitride (RuN), iridium nitride (IrN), osmium nitride (OsN), titanium nitride (TIN), or tantalum nitride (TaN).

The metal-containing layer 250 may be formed by any suitable process. In some embodiments, the metal-containing layer 250 is selectively deposited directly on the bottom 249 by physical vapor deposition (PVD), chemical vapor deposition (CVD), or atomic layer deposition (ALD).

The metal-containing layer 250 may be deposited to any suitable thickness. In one or more embodiments, the metal-containing layer 250 has a thickness in a range of from 10 Angstroms (Å) to 300 Angstroms (Å). The thickness of the metal-containing layer 250 can vary within the range of from 10 Angstroms (Å) to 300 Angstroms (Å) depending on the specific application for which the metal-containing layer 250 is used.

Embodiments of the present disclosure employ blocking compounds that can be used to form a blocking layer 255 on a surface to suppress or prevent subsequent deposition on that surface. It has been advantageously found that blocking compounds, which will be described in further detail herein, can be used to suppress or prevent subsequent deposition on a metallic surface, e.g., metal lines. In specific embodiments, the blocking compounds form a blocking layer 255 that can be used to suppress or prevent subsequent deposition on a metallic surface, e.g., the metal-containing layer 250. Any blocking compound that suppresses or prevents subsequent deposition on a metallic surface, e.g., the metal-containing layer 250 may be used.

In one or more embodiments, the blocking layer 255 is formed directly on the metal-containing layer 250. In one or more embodiments, the composition of the blocking compounds used to form the blocking layer 255 depends on the composition of the metal-containing layer 250.

In some embodiments, the blocking compound comprises one or more of organic ligands or inorganic ligands. In some embodiments, the blocking compound comprises organic ligands. In some embodiments, the blocking compound comprises at least one ketone group. In some embodiments, the blocking compound comprises at least one alkoxy group. In some embodiments, the blocking compound comprises at least one heterocyclic carbene group. In some embodiments, the blocking compound comprises inorganic ligands. In some embodiments, the blocking compound comprises a silicon-containing compound. In some embodiments, the blocking compound comprises at least one silane group. In some embodiments, the blocking compound comprises at least one thiol group. In some embodiments, the blocking compound comprises a phosphonate-containing compound.

In one or more embodiments, the blocking compound comprises a formula R₁—C≡C—R₂, wherein R₁ and R₂ are linear alkyl chains comprising from 5 to 15 carbon atoms. In one or more embodiments, the blocking compound comprises a formula H—C≡C—R₃, wherein R₃ is a linear alkyl chain comprising from 1 to 20 carbon atoms. In one or more embodiments, the blocking compound has a formula of R—SiH₃, wherein R is selected from a linear alkyl chain and a branched alkyl chain comprising from 2 to 20 carbon atoms.

In some embodiments, the processing conditions for exposing the substrate 210 to the blocking compound to form the blocking layer 255 may be controlled and may be varied depending on the composition of the blocking compound.

The substrate 210 may be exposed to the blocking compound at any suitable pressure for forming the blocking layer 255. In some embodiments, the substrate 210 is exposed to the blocking compound at a pressure of less than or equal to about 80 Torr, less than or equal to about 70 Torr, less than or equal to about 60 Torr, less than or equal to about 50 Torr, less than or equal to about 40 Torr, less than or equal to about 30 Torr, less than or equal to about 20 Torr, less than or equal to about 15 Torr, less than or equal to about 10 Torr, or less than or equal to about 5 Torr.

The substrate 210 may be exposed to the blocking compound for any suitable time period to form the blocking layer 255 to a predetermined thickness. In some embodiments, the substrate 210 is exposed to the blocking compound for a time period in a range of from 1 second to 600 seconds.

The substrate 210 may be exposed to the blocking compound at any suitable temperature to form the blocking layer 255. In some embodiments, the substrate 210 is exposed to the blocking compound at a temperature in a range of 150° C. to 400° C., such as, for example, in a range of from 200° C. to 300° C.

The blocking layer 255 may be formed using any suitable deposition technique. In one or more embodiments, the blocking layer 255 is formed in an atomic layer deposition (ALD) chamber. In one or more embodiments, the blocking layer 255 is formed in an ex situ solution processing chamber.

Referring again to FIGS. 1A, 1B, and 1F, in accordance with operation 160 of the method 100, the TMDC film 260 is selectively formed on the sidewalls 248. In one or more embodiments, the TMDC film 260 covers the entirety of the sidewalls 248. In one or more embodiments, the TMDC film 260 does not form on the bottom 149 of the gap 146 due to the presence of the blocking layer 255 on the metal-containing layer 250.

In one or more embodiments, when the blocking layer 255 is not present, the deposition of the TMDC film 260 is substantially conformal, such that the TMDC film 260 forms on the sidewalls 248 and on the metal-containing layer 250 the bottom 249 of the gap 246. In one or more embodiments, when the blocking layer 255 is not present and the metal-containing layer 250 is not present, the deposition of the TMDC film 260 is substantially conformal, such that the TMDC film 260 forms on the sidewalls 248 and on the bottom 249 of the gap 246. As used herein, a layer which is “substantially conformal” refers to a layer where the thickness is about the same throughout (e.g., on the top, middle and bottom of sidewalls 148 and on the bottom 149 of the gap 146). A layer which is substantially conformal varies in thickness by less than or equal to about 5%, 2%, 1% or 0.5%.

As described herein, in one or more embodiments, the TMDC film 260 does not form on the bottom 149 of the gap 146 due to the presence of the blocking layer 255 on the metal-containing layer 250. The TMDC film 260 selectively forms on the sidewalls 248 and extends towards the bottom 249 of the gap 246.

Referring to FIGS. 1A and 1G, at operation 170 of the method 100, the blocking layer 255 is removed. In one or more embodiments, the TMDC film 260 extends towards the bottom 249 of the gap 246 and is in contact with the metal-containing layer 250 after removal of the blocking layer 255. In one or more embodiments, the TMDC film 260 extends towards the bottom 249 of the gap 246 and is not in contact with the metal-containing layer 250 after removal of the blocking layer 255, such as, for example, the illustrated embodiment of FIG. 1G.

In one or more embodiments, removing the blocking layer 255 comprises a thermal process. In one or more embodiments, removing the blocking layer 255 comprises a thermal anneal process. The thermal process, e.g., the thermal anneal process, can be any suitable process that does not include the use of plasma. In one or more embodiments, removing the blocking layer 255 comprises a plasma treatment process. The plasma treatment process can be any suitable process. In one or more embodiments, the plasma treatment process includes a physical vapor deposition (PVD) process. In one or more embodiments, the plasma treatment comprises flowing one or more of hydrogen (H₂) or argon (Ar). In one or more embodiments, the plasma treatment process increases a density of the TMDC film 260.

Referring to FIGS. 1A and 1F, the method 100 includes performing a gap fill process to fill the gap 246 with a gapfill material 280 (operation 180). The gap fill process can include any suitable deposition technique. In one or more embodiments, the gap fill process comprises a physical vapor deposition (PVD) process. The gapfill material 280 may include any suitable material, such as a conductive material. In one or more embodiments, the gapfill material 280 comprises one or more of copper (Cu) or cobalt (Co). In one or more embodiments, the gap fill process comprises filling the gap 246 with one or more of copper (Cu) or cobalt (Co) by physical vapor deposition (PVD).

The gapfill material 280 is substantially free of seams and/or voids or free of seams and/or voids. As used in this regard, “substantially free” means that less than about 5%, including less than about 4%, less than about 3%, less than about 2%, less than about 1%, less than about 0.5%, and less than about 0.1% of the total composition of the gapfill material 280 an atomic basis, comprises seams and/or voids. Advantageously, in one or more embodiments, the gapfill material 280 is free of seams and/or voids.

In one or more embodiments, after filling the gap 246 with the gapfill material 280, a completed interconnect structure, e.g., interconnect structure 190 is formed, such that additional interconnect structures may be formed on top of or below the interconnect structure 290.

In one or more embodiments, the methods described herein comprise an optional post-processing operation. The optional post-processing operation can be, for example, a process to modify film properties (e.g., annealing) or a further film deposition process (e.g., additional ALD or CVD processes) to grow additional films. In some embodiments, the optional post-processing operation can be a process that modifies a property of the deposited film/layer. In some embodiments, the optional post-processing operation comprises annealing the substrate 210. In some embodiments, the annealing process is performed at temperatures in the range of about 300° C., 400° C., 500° C., 600° C., 700° C., 800° C., 900° C. or 1000° C. The annealing environment of some embodiments comprises one or more of an inert gas (e.g., molecular nitrogen (N₂), argon (Ar)) or a reducing gas (e.g., molecular hydrogen (H₂) or ammonia (NH₃)) or an oxidant, such as, but not limited to, oxygen (O₂), ozone (O₃), or peroxides. Annealing can be performed for any suitable length of time. In some embodiments, the substrate 210 is annealed for a predetermined time in the range of about 15 seconds to about 90 minutes, or in the range of about 1 minute to about 60 minutes. In some embodiments, annealing the substrate 210 increases the density, decreases the resistivity and/or increases the purity of the layers, such as the TMDC film 260.

In some embodiments, the substrate 210 is moved from a first chamber to a separate, next chamber for further processing. The substrate 210 can be moved directly from the first chamber to the separate processing chamber, or the substrate 210 can be moved from the first chamber to one or more transfer chambers, and then moved to the separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. However, the exact arrangement and combination of chambers may be altered for purposes of performing specific steps of a process as described herein.

Other processing chambers which may be used include, but are not limited to, cyclic deposition including a deposition step, and an annealing or treatment step, atomic layer deposition (ALD), chemical vapor deposition (CVD), physical vapor deposition (PVD), etch, pre-clean, chemical clean, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants (e.g., reactant). According to one or more embodiments, a purge gas is injected at the exit of the deposition chamber to prevent reactants (e.g., reactant) from moving from the deposition chamber to the transfer chamber and/or additional processing chamber. Thus, the flow of inert gas forms a curtain at the exit of the chamber.

The substrate can be processed in single substrate deposition chambers, where a single substrate is loaded, processed and unloaded before another substrate is processed. The substrate can also be processed in a continuous manner, similar to a conveyer system, in which multiple substrates are individually loaded into a first part of the chamber, move through the chamber and are unloaded from a second part of the chamber. The shape of the chamber and associated conveyer system can form a straight path or curved path. Additionally, the processing chamber may be a carousel in which multiple substrates are moved about a central axis and are exposed to deposition, etch, annealing, cleaning, etc., processes throughout the carousel path.

The substrate can also be stationary or rotated during processing. A rotating substrate can be rotated (about the substrate axis) continuously or in discrete steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

Additional embodiments are directed to a cluster tool used to manufacture the microelectronic devices described herein, e.g., microelectronic device 200, and perform the methods described herein, e.g., method 100. In one or more embodiments, the cluster tool comprises a pre-cleaning chamber to pre-clean the substrate 210 and a deposition chamber for forming the dielectric layer 245. In one or more embodiments, a pre-cleaned substrate comprising a dielectric layer including at least one feature defining a gap having sidewalls and a bottom is provided.

In one or more embodiments, the cluster tool comprises a deposition chamber for selectively depositing the metal-containing layer 250 directly on the bottom 249, a deposition chamber for forming the blocking layer 255, and a deposition chamber for selectively forming the TMDC film 260 on the sidewalls 248. In one or more embodiments, depositing the transition metal oxide film on the sidewalls (in the first phase 160A) and converting the transition metal oxide film to the transition metal dichalcogenide (TMDC) film 260 (in the second phase 160B) are performed in a single processing chamber, such as, for example, a single atomic layer deposition (ALD) chamber. In one or more embodiments, the metal-containing layer 250 can be directly on the bottom 249, the blocking layer 255 can be formed directly on the metal-containing layer 250, and the TMDC film 260 can be selectively formed on the sidewalls 248 in a single atomic layer deposition (ALD) chamber. In one or more embodiments, the cluster tool comprises a chamber for treating the substrate 210 at operation 150 with a plasma treatment or ultraviolet (UV) radiation exposure prior to forming the TMDC film 260.

In one or more embodiments, the cluster tool comprises a chamber for removing the blocking layer 255. Advantageously, in one or more embodiments, the same processing chamber may be used to selectively form the TMDC film 260 and to remove the blocking layer 255. In one or more embodiments, the cluster tool comprises a deposition chamber for performing the gap fill process to fill the gap 246 with the gapfill material 280. In one or more embodiments, the cluster tool comprises a physical vapor deposition (PVD) chamber for performing the gap fill process to fill the gap 246 with the gapfill material 280.

In one or more embodiments, one or more of the operations of the methods described herein are performed in situ, without an intervening vacuum break. In one or more embodiments, each of the operations of the methods described are performed in situ, without an intervening vacuum break. In one or more embodiments, one or more of the operations of the methods described herein are performed ex situ, such that one or more of the processes are performed with an intervening vacuum break.

Another aspect of the disclosure pertains to a non-transitory computer readable medium including instructions, that, when executed by a controller of a processing system, causes the processing system to perform operations of the methods described herein. In one or more embodiments, a non-transitory computer readable medium including instructions, that, when executed by a controller of a processing system, causes the processing system to perform one or more operations of the methods described herein with respect to FIGS. 1A-1H.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of manufacturing a microelectronic device, the method comprising:
forming a dielectric layer on a substrate, the dielectric layer including at least one feature defining a gap having sidewalls and a bottom;
selectively depositing a metal-containing layer directly on the bottom;
forming a blocking layer directly on the metal-containing layer; and
selectively forming a transition metal dichalcogenide film on the sidewalls.

2. The method of claim 1, wherein the metal-containing layer comprises one or more of molybdenum (Mo), tungsten (W), ruthenium (Ru), iridium (Ir), osmium (Os), titanium (Ti), tantalum (Ta), molybdenum nitride (MoN), tungsten nitride (WN), ruthenium nitride (RUN), iridium nitride (IrN), osmium nitride (OsN), titanium nitride (TIN), or tantalum nitride (TaN).

3. The method of claim 1, wherein the metal-containing layer has a thickness in a range of from 10 Angstroms to 300 Angstroms.

4. The method of claim 1, wherein selectively forming the transition metal dichalcogenide film comprises:
depositing a transition metal oxide film on the sidewalls by sequentially exposing the substrate to a transition metal precursor and an oxidant; and
converting the transition metal oxide film to the transition metal dichalcogenide film.

5. The method of claim 4, further comprising treating the substrate prior to depositing the transition metal oxide film, treating the substrate including a plasma treatment or ultraviolet (UV) radiation exposure.

6. The method of claim 4, wherein depositing the transition metal oxide film comprises directly forming the transition metal oxide film without forming a transition metal film intermediate.

7. The method of claim 4, wherein depositing the transition metal oxide film on the sidewalls and converting the transition metal oxide film to the transition metal dichalcogenide film are performed in a single processing chamber.

8. The method of claim 4, wherein the transition metal precursor comprises one or more of bis(t-butylimino) bis(dimethylamino) tungsten (VI), bis(isopropylcyclopentadienyl) tungsten (IV) dihydride, bis(cyclopentadienyl) tungsten dihydride, bis(t-butylimino) bis(dimethylamino) molybdenum (VI), pentakis (dimethylamino) tantalum (V), or tetrakis (dimethylamido) titanium (IV).

9. The method of claim 4, wherein the oxidant comprises one or more of water (H₂O), oxygen (O₂), ozone (O₃), an alcohol, or deionized/deoxygenated water.

10. The method of claim 4, wherein converting the transition metal oxide film to the transition metal dichalcogenide film comprises exposing the transition metal oxide film to a chalcogenide precursor.

11. The method of claim 10, wherein the transition metal oxide film is converted to the transition metal dichalcogenide film at a pressure in a range of from 0.1 Torr to 760 Torr.

12. The method of claim 10, wherein the chalcogenide precursor comprises one or more of sulfur(S), selenium (Se) or tellurium (Te).

13. The method of claim 12, wherein the chalcogenide precursor is hydrogen sulfide (H₂S).

14. The method of claim 1, further comprising removing the blocking layer.

15. The method of claim 14, further comprising performing a gap fill process to fill the gap with a gapfill material.

16. The method of claim 15, wherein the gapfill material comprises one or more of copper (Cu), tungsten (W), molybdenum (Mo), or cobalt (Co).

17. The method of claim 1, performed at a temperature in a range of from 50° C. to 500° C.

18. A method of manufacturing a microelectronic device, the method comprising:
forming a dielectric layer on a substrate, the dielectric layer including at least one feature defining a gap having sidewalls and a bottom;
selectively depositing a metal-containing layer directly on the bottom;
forming a blocking layer directly on the metal-containing layer;
selectively forming a transition metal dichalcogenide film on the sidewalls, selectively forming the transition metal dichalcogenide film comprising:
depositing a transition metal oxide film on the sidewalls by sequentially exposing the substrate to a transition metal precursor and an oxidant; and
converting the transition metal oxide film to the transition metal dichalcogenide film by exposing the transition metal oxide film to a chalcogenide precursor;
removing the blocking layer; and
performing a gap fill process to fill the gap with a gapfill material comprising one or more of copper (Cu), tungsten (W), molybdenum (Mo), or cobalt (Co).

19. The method of claim 18, wherein the metal-containing layer comprises one or more of molybdenum (Mo), tungsten (W), ruthenium (Ru), iridium (Ir), osmium (Os), titanium (Ti), tantalum (Ta), molybdenum nitride (MoN), tungsten nitride (WN), ruthenium nitride (RUN), iridium nitride (IrN), osmium nitride (OsN), titanium nitride (TIN), or tantalum nitride (TaN).

20. The method of claim 18, further comprising treating the substrate prior to depositing the transition metal oxide film, treating the substrate including a plasma treatment or ultraviolet (UV) radiation exposure.
